(19) United States
(12) Patent Application Publication
(10) Pub. No.: US 2017/0294314 A1
(43) Pub. Date: Oct. 12, 2017

(54) GERMANIUM COMPOSITIONS SUITABLE FOR ION IMPLANTATION TO PRODUCE A GERMANIUM-CONTAINING ION BEAM CURRENT

(71) Applicants: Aaron Reinicker, Buffalo, NY (US); Ashwini K. Sinha, East Amherst, NY (US)

(72) Inventors: Aaron Reinicker, Buffalo, NY (US); Ashwini K. Sinha, East Amherst, NY (US)

(21) Appl. No.: 15/483,448

(22) Filed: Apr. 10, 2017

Related U.S. Application Data
(60) Provisional application No. 62/321,069, filed on Apr. 11, 2016.

(51) Int. Cl. H01L 21/265; C23C 14/48

(52) U.S. Cl. CPC H01L 21/265; C23C 14/48

(57) ABSTRACT

The present invention relates to an improved composition for ion implantation. A dopant source comprising GeF₄ and an assistant species comprising CH₃F is provided, wherein the assistant species in combination with the dopant gas can produces a Ge-containing ion beam current. The criteria for selecting the assistant species is based on the combination of the following properties: ionization energy, total ionization cross sections, bond dissociation energy to ionization energy ratio, and a certain composition.

### RELATED APPLICATIONS

The present application claims priority to U.S. Application Ser. No. 62/321,069 filed Apr. 11, 2016, the disclosure of which is hereby incorporated by reference in its entirety for all purposes.

### FIELD OF THE INVENTION

The present invention relates to a composition comprising methyl fluoride, CH₃F, an assistant species, in combination with germanium tetrafluoride, GeF₄, a Ge dopant source to produce a germanium-containing ion beam current.

### BACKGROUND OF THE INVENTION

Ion implantation is utilized in the fabrication of semiconductor based devices such as Light Emitting Diodes (LEDs), solar cells, and Metal Oxide Semiconductor Field Effect Transistors (MOSFETs). Ion implantation is used to introduce dopants to alter the electronic or physical properties of semiconductors.

In a traditional ion implantation system, a gaseous species often referred to as the dopant source is introduced in to the arc chamber of an ion source. The ion source chamber comprises a cathode which is heated to its thermionic generation temperature to generate electrons. Electrons accelerate towards the arc chamber wall and collide with the dopant source gas molecule present in the arc chamber to generate a plasma. The plasma comprises dissociated ions, radicals, and neutral atoms and molecules of the dopant gas species. The ions are extracted from the arc chamber and then separated to select a target ionic species which is then directed towards the target substrate. The amount of ions produced depends upon various parameters of the arc chamber, including, but not limited to, the amount of energy supplied per unit time to the arc chamber, (i.e. power level) and flow rate of the dopant source and/or assistant species into the ion source.

Several dopant sources are currently in use today, such as, fluorides, hydrides, and oxides containing the dopant atom or molecule. These dopant sources can be limited in their ability to produce the beam current of the target ionic species and there is a continuous demand for improving the beam current, especially for high dose ion implantation applications, such as source drain/source drain extension implants, polysilicon doping and threshold voltage tuning. In one example, GeF₄ is a commonly used dopant source for Ge ion implantation. Ge doping of semiconductors have several applications, including preamorphization of Si surfaces for creating ultra shallow junctions, and threshold voltage tuning for gate oxides and electrodes in finFETs.

Today, an increased beam current is achieved by introducing gases which produce ions containing the target dopant species into the plasma. One known method utilized for increasing the beam current generated from ionizing the dopant gas source is the addition of a co-species to the dopant source to produce more dopant ions. For example, U.S. Pat. No. 7,655,931 discloses adding a diluent gas having the same dopant ion as the dopant gas. However, the beam current increase may not be high enough for particular ion implant recipes. In fact, there have been instances where the addition of the co-species actually lowers the beam current. In this regard, U.S. Pat. No. 8,803,112 at FIG. 3 and Comparative Examples 3 and 4 demonstrate that adding a diluent of SiH₄ or Si₂H₆, respectively, to a dopant source of SiF₄ actually lowered the beam current in comparison to the beam current generated solely from SiF₄.

Another method includes using isotopically enriched dopant sources. For example, U.S. Pat. No. 8,883,620 discloses adding isotopically enriched versions of a naturally occurring dopant gas such as GeF₄, in an attempt to introduce more moles of the dopant ion per unit volume. However, utilizing isotopically enriched gases may require substantial changes to the ion implant process that can require re-qualification, which is a time consuming process. Additionally, the isotopically enriched version does not necessarily generate an ion beam current that increases in an amount that is proportional to the isotopic enrichment level. Further, isotopically enriched dopant sources are not readily commercially available. Even when commercially available, such sources can be significantly more expensive than their naturally occurring versions as a result of the process required to isolate the desired isotope of the dopant source above its natural abundance levels. This increase in cost of the isotopically enriched dopant source may sometimes not be justified in view of the observed increase in ion beam current, which for certain dopant sources has been only observed to produce a marginal improvement in ion beam current relative to its naturally occurring version.

In view of these drawbacks, there remains an unmet need for improving the Ge-containing ion beam current.

### SUMMARY OF THE INVENTION

Due to these shortcomings, the present invention relates to a composition comprising CH₃F, a suitable assistant species, in combination with a dopant source, GeF₄, that can generate the Ge-containing ion beam current, which is the target dopant ion (i.e., Ge-containing target ionic species) where the dopant source can also be mixed with other optional diluent species. The criteria for selecting CH₃F as a suitable assistant species is based on the combination of the following properties: ionization energy, total ionization cross sections, bond dissociation energy to ionization energy ratio and a certain composition. It should be understood that other uses and benefits of the present invention will be applicable.

In one aspect, a composition suitable for use in an ion implanter for production of Ge-containing target ionic species to create a Ge-containing ion beam current, said composition comprising: a dopant source comprising GeF₄ from which the Ge-containing target ionic species are derived; and an assistant species comprising CH₃F; wherein the dopant source and the assistant species occupy the ion implanter and interact therein to produce the Ge-containing target ionic species.

### BRIEF DESCRIPTION OF THE DRAWINGS

FIG. 1 is a bar graph of comparing relative ⁷²Ge ion beam current data for ⁷²GeF₄ gas mixtures; and

FIG. 2 is a bar graph comparing relative Ge ion beam current data produced from naturally occurring GeF₄ and isotopically enriched ⁷²GeF₄ gas mixtures.

### DETAILED DESCRIPTION OF THE INVENTION

The relationship and functioning of the various elements of this invention are better understood by the following detailed description. The detailed description contemplates the features, aspects and embodiments in various permutations and combinations, as being within the scope of the disclosure. The disclosure may therefore be specified as comprising, consisting or consisting essentially of, any of such combinations and permutations of these specific features, aspects, and embodiments, or a selected one or ones thereof.

Unless indicated otherwise, it should be understood that all compositions are expressed as volume percentages (vol %), based on a total volume of the composition.

It should be understood that reference to dopant source and assistant species may also include any isotopically enriched version. Specifically, any atom of GeF4 or the assistant species, CH₃F, can be isotopically enriched to greater than natural abundance levels.

As used herein and throughout the specification, the terms “isotopically enriched” and “enriched” dopant gas are used interchangeably to mean the dopant gas contains a distribution of mass isotopes different from the naturally occurring isotopic distribution, whereby one of the mass isotopes has an enrichment level higher than present in the naturally occurring level. By way of example, 58% ⁷²GeF₄ refers to an isotopically enriched or enriched dopant gas containing mass isotope ⁷²Ge at 58% enrichment, whereas naturally occurring GeF₄ contains mass isotope ⁷²Ge at 27% natural abundance levels. The enrichment levels as used herein and throughout are expressed as volume percentages, based on a total volume of distribution of the mass isotopes contained in the material.

It should be understood that the GeF₄ dopant source and the CH₃F assistant species as described herein and throughout may include other constituents (e.g., unavoidable trace contaminants) whereby such constituents are contained in an amount that does not adversely impact the interaction of the CH₃F with GeF₄.

The present disclosure relates to a composition for ion implantation comprising a dopant source, GeF₄, and an assistant species, CH₃F, wherein the assistant species in combination with the dopant gas produces a Ge-containing ion beam current with or without an optional diluent species. The term “Ge-containing target ionic species” or “desired dopant ion” as used herein and throughout is defined as any Ge-containing positively or negatively charged atom or molecular fragment(s) originating from the GeF₄ dopant source that is implanted into the surface of a target substrate, including but not limited to, wafers. The term “GeF₄” as used herein and throughout refers to a dopant source in its naturally occurring form. The term “Ge-containing” as used herein and throughout includes any mass isotope of Ge. As will be explained, the present invention recognizes that there is a need for improvement of current dopant sources, particularly in high dose applications (i.e., greater than 10¹³ atoms/cm²) of ion implantation, and offers a novel solution for achieving the same.

In one aspect, the present invention involves a dopant source GeF₄ comprising the Ge-containing target ionic species and an assistant species comprising CH₃F, in which the assistant species has the following attributes: (i) a lower ionization energy than the dopant source; (ii) a total ionization cross section greater than 2 Å² (iii) a ratio of bond dissociation energy to ionization energy greater than or equal to 0.2; and (iv) a composition characterized by an absence of the target ionic species. Without being bound by any particular theory, the Applicants have discovered that when the assistant species CH₃F with such attributes is co-flowed, sequentially flowed or mixed with the dopant source GeF₄, the GeF4 dopant source and the CH3F assistant species can interact with each other to produce Ge-containing target ionic species.

In another aspect, the GeF₄ dopant source and the CH₃F assistant species can interact with each other to produce a higher Ge-containing ion beam current of Ge-containing ions that that generated solely from the GeF4 dopant source. The ability to produce a higher Ge-containing ion beam current of the Ge-containing target ionic species is surprising, given that the assistant species CH₃F does not contain the Ge-containing target ionic species and, as a result, is diluting the GeF₄ dopant source and reducing the number of GeF₄ dopant source molecules introduced into the plasma. The assistant species CH₃F can enhance the ionization of the dopant source GeF₄ by synergistically interacting with the same to form the Ge-containing target ionic species to enable increase of the Ge-containing ion beam current of the Ge-containing target ionic species from the GeF₄ dopant source, even though the CH₃F assistant species does not include the Ge-containing target ionic species.

The CH₃F assistant species can be mixed with the GeF₄ dopant source in a single storage container. Alternatively, the CH₃F assistant species and GeF₄ dopant source can be co flown from separate storage containers. Still further, the CH₃F assistant species and GeF₄ dopant source can be sequentially flowed from separate storage containers into an ion implanter to produce the resultant mixture. When co-flown or sequentially flowed, the resultant compositional mixture can be produced upstream of the ion chamber or within the ion source chamber. In one example, the compositional mixture is withdrawn in the vapor or gas phase and then flows into an ion source chamber where the gas mixture is ionized to create a plasma. The Ge-containing target ionic species can then be extracted from the plasma and implanted into the surface of a substrate.

The ionization energy as used herein refers to the energy required to remove an electron from an isolated gas species and form a cation. The values for ionization energy can be obtained from the literature. More specifically, the literature sources can be found in the National Institute of Standards and Technology (NIST) chemistry webbook (P. J. Linstrom and W. G. Mallard, Eds., NIST Chemistry WebBook, NIST Standard Reference Database Number 69, National Institute of Standards and Technology, Gaithersburg Md., 20899. http://webbook.nist.govichemistry/). Values for ionization energy can be determined experimentally using electron impact ionization, photoelectron spectroscopy, or photoionization mass spectrometry. Theoretical values for ionization energy can be obtained using density functional theory (DFT) and modeling software, such as commercially available Dacapo, VASP, and Gaussian. Although the energy supplied to the plasma is a discrete value, the species in the plasma are present over a broad distribution of different energies. In accordance with the principles of the present invention, when an assistant species with a lower ionization energy than the dopant source is added or introduced with the dopant source, the assistant species can ionize over a larger distribution of energies in the plasma. As a result, the overall population of ions in the plasma can increase. Such an increased population of ions can lead to “assistant species ion-assisted ionization” of the dopant species as a result of the ions of the assistant species accelerating in the presence of the electric field and colliding with the dopant source to further break it down into more fragments. The net result can be an increase in Ge-containing ion beam current for the Ge-containing target ionic species. On the contrary, if a species with a higher ionization energy than the dopant source is introduced into the dopant source, the added species can form a lower percentage of ions compared to the ions generated from the dopant source which can reduce the overall percentage of ions in the plasma and can reduce the Ge-containing ion beam current of the Ge-containing target ionic species. In accordance with the principles of the present invention, the selected assistant species, CH₃F, has an ionization energy of 13.1 eV, while the ionization energy of the selected dopant source, GeF₄ is 15.7 eV.

Although having an assistant species with a lower ionization energy than the dopant source is desirable, the present invention recognizes that lower ionization energy by itself may not increase Ge-containing ion beam current. Other applicable criteria must be met in accordance with the principles of the present invention. Specifically, the assistant species must have a minimum total ionization cross section. The total ionization cross section (TICS) of a molecule or atom as used herein is defined as the probability of the molecule or the atom forming an ion under electron and/or ion impact ionization represented in units of Area (e.g., cm², A², m²) as a function of the electron energy in eV. It should be understood that TICS as used herein and throughout refers to a maximum value at a particular electron energy. Experimental data and BEB estimates are available in the literature and through the National Institute of Standards and Technology (NIST) database (Kim, Y., K. et al., Electron-Impact Cross Sections for Ionization and Excitation Database 107, National Institute of Standards and Technology, Gaithersburg Md., 20899, http://physics.nist.gov/PhysRefData/Ionization/molTable.html.) TICS values can be determined experimentally using electron impact ionization or electron ionization dissociation. The TICS can be estimated theoretically using the binary encounter Bethe (BEB) model. As the number of collision events in the plasma increases, the number of bonds broken increases and the number of ion fragments increases. Hence, besides a lower ionization energy, the present invention has discovered that a sufficient total ionization cross-section for the assistant species is also a desired property to assist with the ionization of the dopant species. In a preferred embodiment, the assistant species has a TICS that is greater than 2 Å². Applicants have discovered that an ionization cross-section greater than 2 Å² provides sufficient likelihood that the necessary collisions can occur. The assistant species, CH₃F, has a TICS of 4.4 Å². On the contrary, if the ionization cross section is less than 2 Å², Applicants have observed that the number of collision events in the plasma is expected to decrease and, as a result, the Ge-containing ion beam current can also decrease. As an example, H₂ has a total ionization cross section less than 2 Å², and when added to a dopant source such as GeF₄, the Ge-containing ion beam current is observed to decrease relative to that generated solely from GeF₄.

In addition to the requisite ionization energy and TICS, the assistant species that is selected must also have a certain bond dissociation energy (BDE) such that a ratio of the BDE of a weakest bond of the assistant species to the ionization energy of the assistant species is 0.2 or higher. Values for BDE are readily available in the literature, and more specifically from the National Bureau of Standards (Darwent, B. deB., “Bond Dissociation Energies in Simple Molecules”, National Bureau of Standards, (1970)) or from textbooks (Speight, J. G., Lange, N. A., Lange's Handbook of Chemistry, 16^{th} ed., McGraw-Hill, 2005). BDE values can also be experimentally determined through techniques such as pyrolysis, calorimetry, or mass spectrometry and also can be determined theoretically through density functional theory and modeling software, such as commercially available Dacapo, VASP, and Gaussian. The ratio is an indicator of the proportion of ions that can be produced in the plasma relative to uncharged species. The BDE can be defined as the energy required to break a chemical bond. The bond with the weakest BDE will be the most likely to initially break in the plasma. Therefore, this metric is calculated using the weakest bond dissociation energy in the molecule, as each molecule can have multiple bonds with differing energies.

Generally speaking, in a plasma, chemical bonds are broken by collisions to produce molecular fragments. For example, GeF₄ can break apart into Ge, GeF, GeF₂, and GeF₃ and F fragments. If the target ionic species is Ge, then four Ge—F bonds must be broken to produce the target ionic species. Conventional wisdom dictates that molecules with relatively lower BDE is preferable, as it would more easily form the target ionic species because the chemical bonds can break more easily. However, the Applicants have discovered otherwise. Applicants have discovered that molecules with a relatively higher BDE tend to produce a greater proportion of ions compared to free radicals and/or neutrals. When a chemical bond is broken specifically in a plasma, the resulting species will form either ions, free radicals, or neutral species. The ratio of BDE of the weakest bond of the assistant species to ionization energy of the assistant species is selected in accordance with the principles of the present invention to be 0.2 or higher so as to increase the proportion of ions in the plasma while reducing the proportion of free radicals and neutral species, as both the free radicals and neutral species have no charge and, therefore, are not influenced by electric fields or magnetic fields. Further, these species are inert in a plasma and cannot be extracted to form an ion beam. Accordingly, the ratio of the BDE of the weakest bond of the assistant species to the ionization energy of the assistant species is an indicator of the fraction of ions formed in the plasma relative to the free radicals and neutral species. The assistant species, CH₃F, has a ratio of weakest bond dissociation energy for the C—H bond to ionization energy of 0.35. As a result, because the CH₃F has a ratio of bond dissociation of the weakest bond to ionization energy of higher than 0.2, the addition of CH₃F to the GeF₄ dopant source can enhance the likelihood that a greater proportion of ions compared to free radical and neutral species is produced in the plasma. The greater proportion of ions can increase the Ge-containing ion beam current of the target ionic species. On the contrary, if the ratio of bond dissociation energy of the weakest bond to ionization energy is below 0.2, the energy supplied to the plasma is coupled to forming a higher proportion of neutral species and/or free radicals which can flood the plasma and decrease the number of target ionic species produced. Hence, this non-dimensional metric of the present invention allows a better comparison between the ability of species to produce a higher proportion of ions relative to free radicals and/or neutrals in the plasma.

The assistant species preferably has a composition that is characterized by an absence of the Ge-containing target ionic species. The ability to utilize such assistant species is unexpected, as less moles of dopant source per unit volume is introduced into the plasma, and thus has the effect of diluting the dopant source in the plasma. However, when the assistant species meets the criteria described previously, the assistant species, when added to the GeF₄ dopant source or vice versa, can increase the Ge-containing ion beam current of the Ge-containing target ionic species compared to the Ge-containing ion beam current generated solely from the GeF₄ dopant source. The target ionic species is Ge-containing and derived from the dopant source GeF₄. The assistant species, CH₃F, enhances the formation of the Ge-containing target ionic species from the GeF₄ dopant source to increase the Ge-containing ion beam current. The increase in Ge-containing ion beam current, relative to that produced solely from GeF₄, may be 5% or higher; 10% or higher; 20% or higher; 25% or higher; or 30% or higher. The exact percentage by which the Ge-containing ion beam current is increased can be a result of selected operating conditions, such as, by way of example, power level of the ion implanter and/or flow rate of the GeF₄ dopant source and CH₃F assistant species gases introduced into the ion implanter.

A preferred assistant species to enhance the Ge-containing ion beam current of the Ge-containing target ionic species from the dopant source has a lower ionization energy than the dopant source; a total ionization cross-section greater than 2 Å²; and a ratio of weakest bond dissociation energy to ionization energy of 0.2 or higher. The assistant species does not contain the Ge-containing target ionic species as the purpose of the assistant species is to enhance formation of the Ge-containing target ionic species from the GeF₄ dopant source. The selection of CH₃F as the assistant species meets the criteria described herein. The combination of the CH₃F assistant species with the GeF₄ dopant source preferably generates an ion beam capable of doping at least 10¹¹ atoms/cm² of the Ge-containing target ionic species from the dopant source.

In another aspect of the present invention, the operating conditions of the ion source can be adjusted such that the composition of the GeF₄ dopant source and CH₃F assistant species is configured to generate a Ge-containing ion beam current that is the same or less than the Ge-containing ion beam current generated solely from the GeF₄ dopant source with or without an optional diluent. Operating at such beam current levels can create other operational benefits. By way of example, some of the operational benefits include but are not limited to reduction of beam glitching, increased beam uniformity, limited space charge effects and beam expansion, limited particle formation, and increased source lifetime of the ion source, whereby all such operational benefits are being compared to the use of GeF₄ solely as the dopant source. The operational conditions which may be manipulated, include, but are not limited to, arc voltage, arc current, flow rate, extraction voltage and extraction current or any combination thereof. Additionally, the ion source may include use of one or more optional diluent, which can include H₂, N₂, He, Ne, Ar, Kr, and/or Xe.

It should be understood that the ions produced from ionization of the assistant species can be selected to be implanted into the target substrate.

Various operating conditions can be used to carry out the present invention. For example, the arc voltage can be in a range of 50-150 V; the flow rate of each of the dopant gas and assistant species into the ion implanter can be in in a range of 0.1-100 sccm; and the extraction voltage can be in a range of 500V to 50 kV. Preferably, each of these operating conditions is selected to achieve a source life of at least 50 hours; so as to produce a Ge-containing ion beam current between 10 microamps and 100 mA.

The concentration for the CH₃F assistant species is selected to be preferably maintained within a range. In particular, the amount of CH₃F can neither be below 1 vol % nor above 50 vol %, based on a total volume of the GeF₄ and CH₃F, in order to avoid any deleterious effects. The amount of CH₃F must be above a minimum level of 1 vol % to reduce the effects of the halogen cycle so that the weight gain of the cathode filament is reduced. At levels below 1 vol % CH₃F, there may be an insufficient amount of CH₃F to produce a boost in the Ge-containing ion beam current. Additionally, the amount of CH₃F does not preferably exceed an upper limit of 50 vol %. When the amount of CH₃F exceeds 50 vol %, the plasma can become flooded with excess CH₃F species which potentially causes the Ge-containing ion beam current improvement to not be produced. Other concentrations may include 10-40 vol % CH₃F with balance GeF₄, preferably 15-40 vol % CH₃F with balance GeF₄ and more preferably 20-40 vol % CH₃F with balance GeF₄.

The present invention contemplates various fields of use for the compositions described herein. For example, some methods include but are not limited to beam line ion implantation and plasma immersion ion implantation mentioned in patent U.S. Pat. No. 9,165,773, which is incorporated herein by reference in its entirety. Further, it should be understood that the compositions disclosed herein may have utility for other applications besides ion implantation, in which the primary source comprises a target species and the assistant species does not contain the target species and is further characterized as meeting the criteria (i), (ii) and (iii) mentioned hereinbefore. For example, the compositions may have applicability for various deposition processes, including, but not limited to, chemical vapor deposition or atomic layer deposition.

The compositions of the present invention can also be stored and delivered from a container with a vacuum actuated check valve that can be used for sub atmospheric delivery, as described in U.S. Patent Application with Docket No. 14057-US-P1, which is incorporated herein by reference in its respective entirety. Any suitable delivery package may be employed, including those described in U.S. Pat. Nos. 5,937,895; 6,045,115; 6,007,609; 7,708,028; 7,905,247; and U.S. Ser. No. 14/638,397 (U.S. Patent Publication No. 2016-0258537, each of which is incorporated herein by reference in its respective entirety. When the compositions of the present invention are stored as a mixture, the mixture in the storage and delivery container may also be present in the gas phase; a liquid phase in equilibrium with the gas phase wherein the vapor pressure is high enough to allow flow from the discharge port; or an adsorbed state on a solid media, each of which is described in U.S. Patent Application with Docket No. 14057-US-P1. Preferably, the composition of assistant species and dopant source will be able to generate a beam of the target ionic species to implant of 10¹¹ atoms/cm² or higher. Alternatively, the dopant source and/or the assistant species is held in a storage and dispensing assembly in an adsorbed state, a free source state or a liquefied source state.

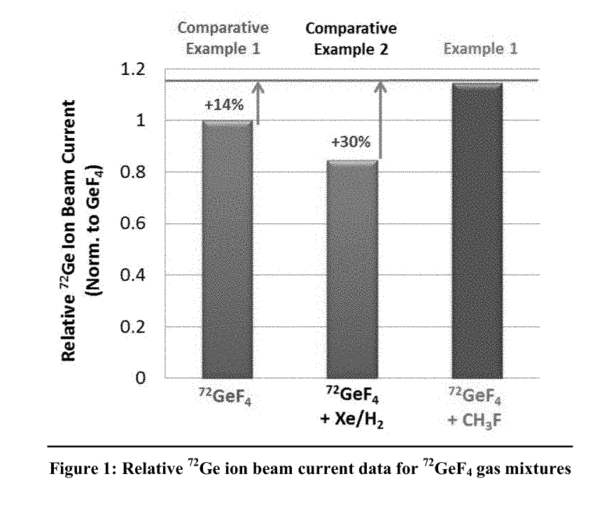

Applicants have performed several experiments as a proof of concept using GeF₄ as a dopant source and CH₃F as an assistant species. In each experiment, the ion beam performance was measured using the Ge ion beam current produced; and the weight change of components was measured within the ion source chamber to measure the performance of the ion source. A cylindrical ion source chamber was used to generate a plasma. The ion source chamber consisted of a helical tungsten filament, tungsten walls, and a tungsten anode perpendicular to the axis of the helical filament. A substrate plate was positioned in front of the anode to keep the anode stationary during the ionization process. A small aperture in the center of the anode and a series of lenses placed in front of the anode were used to generate an ion beam from the plasma and a velocity filter was used to isolate specific ion species from the ion beam. A faraday cup was used to measure the current from the ion beam and all tests were run at an arc voltage of 100 V. The extraction voltage was the same value for each experiment. The entire system was contained in a vacuum chamber capable of reaching pressures less than 1e-7 Torr. FIG. 1 shows a bar graph of the ⁷²Ge ion beam current relative to the ⁷²Ge ion beam current produced solely by ⁷²GeF₄ for each gas mixture tested.

### COMPARATIVE EXAMPLE 1

### ⁷²GeF4

A test was performed to determine the ion beam performance of the dopant gas composition of ⁷²GeF₄ that was isotopically enriched to 50.1 vol %. The ⁷²GeF₄ was introduced into the ion source chamber. A current was applied to the filament to generate electrons and a voltage was applied to the anode to ionize the ⁷²GeF₄ and produce ⁷²Ge ions. The ⁷²Ge ion beam current was normalized to be the basis for comparing the ⁷²Ge ion beam current of other gas mixtures. Results are shown at FIG. 1. A significant filament weight gain occurred of 160 milligrams after 52 minutes of operation at which point the experiment was terminated as the filament could no longer sustain a plasma after 52 minutes. This was equivalent to a filament weight gain rate of 185 mg/hr.

### COMPARATIVE EXAMPLE 2

### 75 vol % ⁷²GeF₄+25 vol % Xe/H₂

Another test was performed to determine the ion beam performance of the dopant gas composition of 75 vol % ⁷²GeF₄ (isotopically enriched in mass isotope ⁷²Ge to 50.1 vol %) mixed with 25 vol % Xe/H₂. The same ion source chamber was utilized as that in Comparative Example 1. The ⁷²GeF₄ and Xe/H₂ were introduced from separate storage containers and mixed before entering the ion source chamber. A current was applied to the filament to generate electrons and a voltage was applied to the anode to ionize the gas mixture and produce ⁷²Ge ions. The ⁷²Ge ion beam current was measured and determined to be about 16% less than the ⁷²Ge ion beam current produced solely using ⁷²GeF₄. Results are shown at FIG. 1. A weight loss of 30 milligrams was observed for the filament over the course of 15 hours of operation. The weight change of the filament with time was roughly −2 mg/hour which indicated a significant improvement over ⁷²GeF₄.

### EXAMPLE 1

### 75 vol % ⁷²GeF₄+25 vol % CH₃F

Another test was performed to determine the ion beam performance of the dopant gas composition of 75 vol % ⁷²GeF₄ (isotopically enriched in mass isotope 72 Ge to 50.1 vol %) mixed with 25 vol % CH₃F. The same ion source chamber was utilized as that in Comparative Example 1. The ⁷²GeF₄ and CH₃F were introduced from separate storage containers and mixed before entering the ion source chamber. A current was applied to the filament to generate electrons and a voltage was applied to the anode to ionize the gas mixture and produce ⁷²Ge ions. The ⁷²Ge ion beam current was measured and determined to be about 14% greater than the ⁷²Ge ion beam current produced using solely ⁷²GeF₄ and 30% greater than the ⁷²Ge ion beam current generated with 75 vol % ⁷²GeF₄ mixed with 25 vol % Xe/H₂. The results are shown in FIG. 1. A weight loss of 16 milligrams was observed over the course of 12 hours of operation or −1.33 mg/hr indicating a significant improvement over ⁷²GeF₄ and similar behavior to the 75 vol % ⁷²GeF₄ mixed with 25 vol % Xe/H₂.

The results of the experiments in FIG. 1 show that although CH₃F diluted the volume of GeF₄, it improved the Ge ion beam current significantly while also improving the performance of the ion source compared to solely using GeF₄. Relative to the mixture in Comparative Example 1, the addition of Xe/H₂ improved the performance of the ion source but reduced the Ge ion beam current compared to the Ge ion beam current produced solely from GeF₄.

### COMPARATIVE EXAMPLE 3

### 50 vol % ⁷²GeF₄+50 vol % Xe/H₂

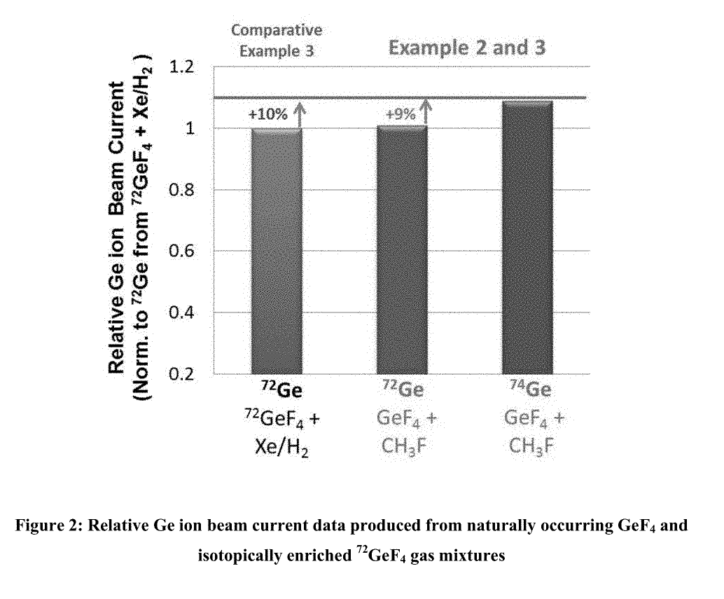

Another test was performed to determine the ion beam performance of the dopant gas composition of 50 vol % ⁷²GeF₄ (isotopically enriched in mass isotope ⁷²Ge to 50.1 vol %) mixed with 50 vol % Xe/H₂. The same ion source chamber was utilized as for all previous examples. The ⁷²GeF₄ and Xe/H₂ were introduced from separate storage containers and mixed before entering the ion source chamber. A current was applied to the filament to generate electrons and a voltage was applied to the anode to ionize the gas mixture and produce ⁷²Ge ions. The flow rate of ⁷²GeF₄ in this experiment was significantly higher than the previous examples, thereby making relevant Ge-containing ion beam current comparisons not possible. The ⁷²Ge ion beam current from this mixture was normalized to compare the ⁷²Ge and ⁷⁴Ge ion beam currents from the naturally occurring GeF₄ mixtures shown in FIG. 2. Under the operating conditions in these experiments, the ⁷²Ge ion beam current from 50 vol % ⁷²GeF₄+50 vol % Xe/H₂ and 75 vol % ⁷²GeF₄+25 vol % Xe/H₂ were equivalent. Results are shown in FIG. 2. A weight gain rate of 0.78 mg/hr was observed, which was significantly lower than the weight gain of 185 mg/hr for ⁷²GeF₄ and comparable to the weight loss of 2 mg/hr of 75 vol % ⁷²GeF₄ (isotopically enriched) mixed with 25 vol % Xe/H₂.

### EXAMPLES 2 AND 3

### 70 vol % GeF₄+30 vol % CH₃F

Another test was performed to determine the ion beam performance of the dopant gas composition of 70 vol % natural GeF₄ mixed with 30 vol % CH₃F. The same ion source chamber was utilized as for previous examples. The natural GeF₄ and CH₃F were introduced from separate storage containers and mixed before entering the ion source chamber. A current was applied to the filament to generate electrons and a voltage was applied to the anode to ionize the gas mixture and produce both ⁷²Ge and ⁷⁴Ge ions. The natural GeF₄ had a level for ⁷²Ge of 27.7% and a level for ⁷⁴Ge of 35.9%, whereas the isotopically enriched ⁷²GeF₄ was enriched in ⁷²Ge to 50.1% while the ⁷⁴Ge had a level of 23.9%. The Ge ion beam current of both ⁷²Ge and ⁷⁴Ge was measured. Both results are shown in FIG. 2 relative to the ⁷²Ge ion beam current from 50 vol % ⁷²GeF₄ mixed with 50 vol % Xe/H₂ of Comparative Example 3. The ion beam current of ⁷⁴Ge from 70 vol % natural GeF₄ with 30 vol % CH₃F was 10% higher than the ⁷²Ge ion beam current generated from 50 vol % isotopically enriched ⁷²GeF₄ with 50 vol % Xe/H₂.

A weight gain rate of 2 mg/hr was observed over the course of operation which was similar in behavior to the weight gain of 0.78 mg/hr for 50 vol % isotopically enriched ⁷²GeF₄ with 50 vol % Xe/H₂.

The results of FIG. 2 were surprising given that the level of ⁷²Ge enrichment in isotopically enriched ⁷²GeF₄ was 14.2 vol % higher than ⁷⁴Ge in naturally occurring GeF₄. It was also surprising that the ⁷²Ge ion beam current from both mixes (Comparative Example 3 and Examples 2 and 3) were observed to be within 1% of each other given that the enrichment level in ⁷²GeF₄ was 22.4 vol % higher than in natural GeF₄, and conventional wisdom would have expected the mixture of 50 vol % Xe/H₂ with 50 vol % enriched ⁷²GeF₄ to produce a higher beam current.

While it has been shown and described what is considered to be certain embodiments of the invention, it will, of course, be understood that various modifications and changes in form or detail can readily be made without departing from the spirit and scope of the invention. It is, therefore, intended that this invention not be limited to the exact form and detail herein shown and described, nor to anything less than the whole of the invention herein disclosed and hereinafter claimed.

1. A composition suitable for use in an ion implanter for production of Ge-containing target ionic species to create a Ge-containing ion beam current, said composition comprising:
a dopant source comprising GeF₄ from which the Ge-containing target ionic species are derived; and
an assistant species comprising CH₃F;
wherein the dopant source and the assistant species occupy the ion implanter and interact therein to produce the Ge-containing target ionic species.

2. The composition of claim 1, wherein the Ge-containing target ionic species creates the Ge-containing ion beam current at a level higher than that generated solely from the dopant source.

3. The composition of claim 1, wherein the Ge-containing target ionic species creates the Ge-containing ion beam current at a level equal to that generated solely from the dopant source.

4. The composition of claim 1, wherein a level of CH₃F ranges from 1 vol %-50 vol % balanced by GeF₄, based on a total volume of the composition.

5. The composition of claim 1, wherein any atom of the dopant source GeF₄ or the assistant species CH₃F is isotopically enriched to greater than natural abundance levels.

6. The composition of claim 1, wherein the dopant source and/or the assistant species is held in a storage and dispensing assembly in an adsorbed state, a free source state, or a liquefied source state.

7. The composition of claim 1, wherein the Ge-containing target ionic species comprises Ge-containing positively or negatively charged atom or molecular fragment(s) originating from the GeF₄ dopant source that is implanted into the surface of a target substrate.

8. The composition of claim 1, wherein the Ge-containing ion beam current is created at a power level and a flow rate whereby the Ge-containing ion beam current is 5% or higher in comparison to a Ge-containing ion beam current generated solely from the dopant source at the power level and the flow rate.

9. The composition of claim 1, wherein the Ge-containing ion beam current is created at a power level and a flow rate whereby the Ge-containing ion beam current is 10% or higher in comparison to a Ge-containing ion beam current generated solely from the dopant source at the power level and the flow rate.

10. The composition of claim 1, wherein the Ge-containing ion beam current is created at a power level and a flow rate whereby the Ge-containing ion beam current is 20% or higher in comparison to a Ge-containing ion beam current generated solely from the dopant source at the power level and the flow rate.

11. The composition of claim 1, wherein the Ge-containing ion beam current is created at a power level and a flow rate whereby the Ge-containing ion beam current is 25% or higher in comparison to a Ge-containing ion beam current generated solely from the dopant source at the power level and the flow rate.

12. The composition of claim 1, wherein the Ge-containing ion beam current is created at a power level and a flow rate whereby the Ge-containing ion beam current is 30% or higher in comparison to a Ge-containing ion beam current generated solely from the dopant source at the power level and the flow rate.

13. The composition of claim 1, wherein the Ge-containing target ionic species creates the Ge-containing ion beam current at a level lower than that generated solely from the dopant source.

14. The composition of claim 4, wherein the level of CH₃F ranges from 15 vol %-40 vol % balanced by GeF₄, based on a total volume of the composition.

15. The composition of claim 4, wherein the level of CH₃F ranges from 20 vol %-40 vol % balanced by GeF₄, based on a total volume of the composition.

16. The composition of claim 1, wherein the dopant source and the assistant species is pre-mixed in a delivery source.

17. The composition of claim 1, wherein the dopant source and the assistant species are co-flowed into the ion implanter.

18. The composition of claim 1, wherein the dopant source and the assistant species is sequentially flowed to an ion chamber.

19. The composition of claim 1, wherein the composition further comprises an optional diluent species.

20. The composition of claim 19, wherein the optional diluent species is selected from the group consisting of H₂, N₂, He, Ne, Ar, Kr and Xe.
